(19) United States
(12) Patent Application Publication
(10) Pub. No.: US 2002/0118033 A1
(43) Pub. Date: Aug. 29, 2002

(54) IC tester and method of cooling the IC tester

(76) Inventor: Hiromichi Koide, Tokyo (JP)

Correspondence Address: FLYNN, THIEL, BOUTELL & TANIS, P.C., 2026 Rambling Road, Kalamazoo, MI, 49008-1699, US

(21) Appl. No.: 10/079,669

(22) Filed: Feb. 20, 2002

(30) Foreign Application Priority Data
Feb. 23, 2001 (JP) 2001-47819

(51) Int. Cl. G01R 31/02

(52) U.S. Cl. 324/760

(57) ABSTRACT

An IC tester and a method of cooling the IC tester capable of reducing an installing space of the IC tester. The IC tester has circulating means for circulating cooling air therein, thereby cooling heating elements.

### BACKGROUND OF THE INVENTION

1. Field of the Invention

The invention relates to an IC tester for inspecting ICs (integrated circuits) and a method of cooling the IC tester.

2. Description of the Related Art

It is well known that ICs are inspected by an IC tester. This IC tester inspects the operation of each IC based on data outputted by each IC when a variety of pattern data are inputted thereto. Such an IC tester is structured in the shape of racks as shown in FIG. 2, wherein depicted by 10 is an IC tester body, 11, 12 are ducts, 13 a cooling stand disposed at both sides of the IC tester body 10 for storing heat exchangers 14 therein. Three ducts 11 are disposed at the upper portion of the IC tester body 10 so as to communicate with each other. The ducts 12 are provided at both side ends of the ducts 11, i.e. over each cooling stand 13, whereby each cooling stand 13 and each duct 11 communicates with each other. Fans 13A are intervened between each duct 12 and each cooling stand 13, although the fan 13A at the left side in FIG. 2 is not shown.

With the IC tester having the foregoing construction, an ambient cooling air is drawn inside the IC tester body 10 through the lower portion of the IC tester body 10, and it is heated by the IC tester body 10, then discharged through the ducts 11 provided at the upper portion of the IC tester body 10. The cooling air inside the ducts 11 is drawn from the ducts 11 to the ducts 12 by the operation of the fans 13A, then it is taken in the cooling stands 13 through the ducts 12. The cooling air taken in the cooling stands 13 is cooled by the heat exchangers 14 at a temperature equivalent to an ambient temperature, then discharged from both sides of the cooling stands 13 to the outside. That is, with the construction of the IC tester, the direction of the cooling air taken in from the lower portion of the IC tester body 10 is sequentially changed and finally the cooling air is discharged from both sides of the cooling stands 13 to the outside.

However, with the IC tester having the foregoing construction, since the ducts 11, 12 and the cooling stands 13 are disposed so as to surround the IC tester body 10, the entire structure of the IC tester including the IC tester body 10 is enlarged, causing a problem that an installing space for the IC tester is needed by the enlarged amount, leading to increase the cost for the IC tester. Further, since the cooling air is discharged from both sides of the cooling stands 13 to the outside, it is necessary to secure a space at both sides of the cooling stands 13 to some extent, causing a problem that an installing space thereof is enlarged.

Further, there is an additional serial problem that an ambient environment (heating or dust control environment) at both sides of the cooling stands 13 is deteriorated because the cooling air is discharged from both sides of the cooling stands 13. It should be noted that the IC tester has to be used in a clean environment. If the cooling air is discharged from both sides of the cooling stands 13, there occurs a case where remaining dust soars at the concerned both sides, and the temperature increases so that the environment is locally deteriorated.

The applicant who is the same as the applicant of Japanese Patent Application No. 2000-297483 has filed the application for a similar invention on Sep. 28, 2001. The invention of the earlier application has intended for reducing an installing space of the IC tester and also reducing a cost but not intended for reducing the deterioration of the ambient environment.

### SUMMARY OF THE INVENTION

The invention has been developed in view of the foregoing problems and it is an object of the invention to provide an IC tester and a method of cooling the IC tester capable of reducing an installing space of an IC tester and of preventing the deterioration of an ambient environment.

To achieve the above object, a first aspect of the invention is an IC tester characterized in having circulating means J for circulating cooling air therein, thereby cooling heating elements mounted therein.

A second aspect of the invention is the IC tester characterized in that the circulating means J in the first aspect of the invention includes cooling means 6 for cooling the cooling air at a constant temperature and supplying it to the heating elements.

A third aspect of the invention is the IC tester characterized in that the heating elements in the first or second aspect of the invention are shelves 1A1, 1A2 through which air is ventilated freely and on which a plurality of printed boards are mounted for effecting various signal processing for testing the ICs.

A fourth aspect of the invention is a method of cooling an IC tester characterized in comprising the step of circulating cooling air in the IC tester, thereby cooling heating elements mounted therein.

A fifth aspect of the invention is the method of cooling an IC tester characterized in further comprising the step of cooling the cooling air at a constant temperature and supplying it to the heating elements.

A sixth aspect of the invention is the method of cooling an IC tester characterized in that the heating elements comprise shelve 1A1, 1A2 through which air is ventilated freely and on which a plurality of printed boards are mounted for effecting various signal processing for testing the ICs.

### BRIEF DESCRIPTION OF THE DRAWINGS

FIG. 1 is a perspective view showing the construction of an IC tester according to a preferred embodiment of the invention.

FIG. 2 is a perspective view showing the construction of a conventional IC.

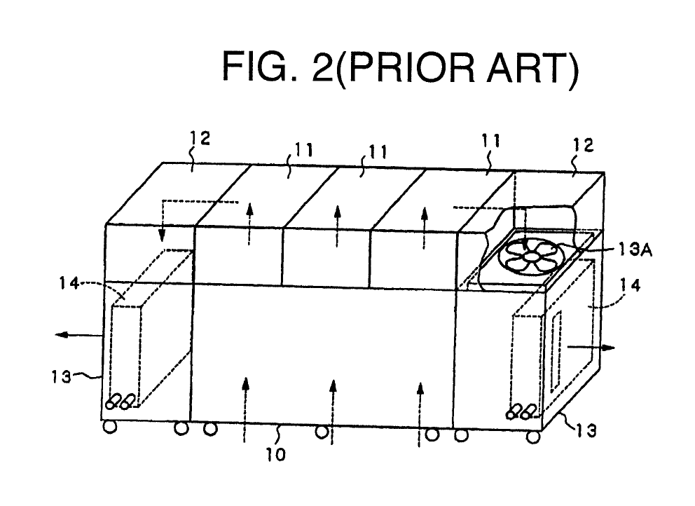

### PREFERRED EMBODIMENT OF THE INVENTION

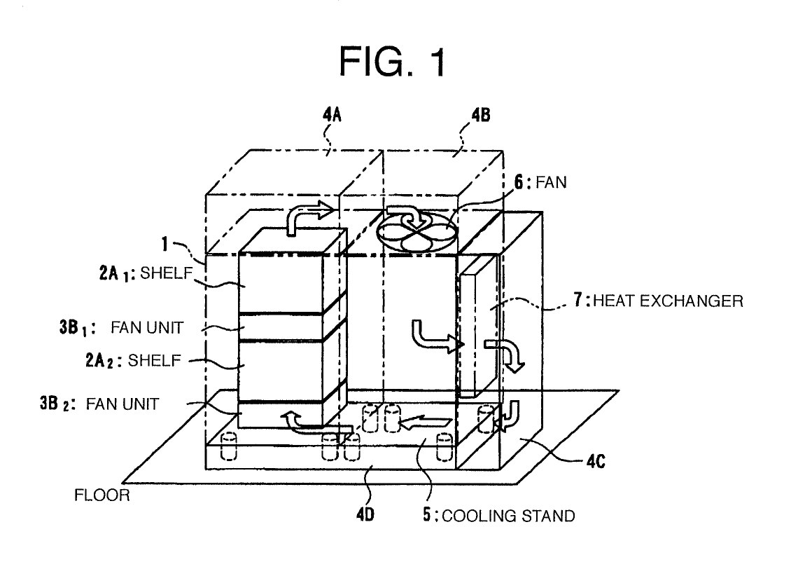

An IC tester and a method of cooling the IC tester according to a preferred embodiment of the invention is described hereinafter with reference to FIG. 1.

FIG. 1 is a perspective view showing the construction of the IC tester according to the preferred embodiment of the invention. In FIG. 1, the IC tester comprises an IC tester body 1, shelves 2A1, 2A2, fan units 3B1, 3B2, ducts 4A to 4D, a cooling stand 5, a fan 6 (cooling means) and a heat exchanger 7. The shelves 2A1, 2A2 are stored in the IC tester body 1 in a state where they are vertically stacked, and the fan units 3B1, 3B2 are disposed respectively under the shelves 2A1, 2A2. The IC tester body 1, the shelves 2A1, 2A2, the fan units 3B1, 3B2, the ducts 4A to 4D, the cooling stand 5, the fan 6 and the heat exchanger 7 constitute circulating means J according to the invention.

That is, the shelves 2A1, 2A2 and the fan units 3B1, 3B2 are laminated and stored in the IC tester body 1 in the descending order of the shelf 2A1, fan unit 3B1, shelf 2A2 and fan unit 3B2. Printed boards (heating elements) are mounted inside the shelves 2A1, 2A2 in a vertical direction and cooling air supplied from the fan units 3B1, 3B2 passes through the surfaces of the printed boards and escapes from the lower side to the upper side of the shelves and the fan units, namely, it is freely ventilated through the shelves and the fan units.

The duct 4A is disposed on the upper portion of the IC tester body 1 and the duct 4B is disposed at one side of the duct 4A while the cooling stand 5 is disposed on the lower portion of the duct 4B and the duct 4C is disposed aside the cooling stand 5. Further, the duct 4D is disposed at the side of the cooling stand 5, namely, disposed commonly under the cooling stand 5 and the IC tester body 1. That is, the cooling air blown through the upper portion of the IC tester body 1 is circulated in a circulating path comprising and directing through the duct 4A→the duct 4B→the cooling stand 5→the duct 4C→the duct 4D→the IC tester body 1 (lower portion).

The fan 6 is provided over the cooling stand 5, namely, at the boundary between the cooling stand 5 and the duct 4B, while the heat exchanger 7 is provided at the side of the cooling stand 5, namely, at the boundary between the cooling stand 5 and the duct 4C. The fan 6 forcibly circulates the cooling air along the circulating path while the heat exchanger 7 watercools the cooling air entering from the cooling stand 5 to the duct 4C at a given target temperature and cools the cooling air by exchanging heat between itself and cooling water, not shown.

The heat exchanger 7 is provided with a temperature sensor for detecting the temperature of the cooling air flowing in the direction of the duct 4C. The operation of the heat exchanger 7 is controlled in the manner that the temperature of the cooling air flowing in the direction of the duct 4C becomes equal to the given target temperature on the basis of the difference between the temperature detected by the temperature sensor and the target temperature set in advance.

With the IC tester having the forgoing construction, the cooling air circulates along the circulating path inside the IC tester body without being discharged outside so as to cool the printed boards serving as heating elements. Accordingly, the IC tester according to the invention does not deteriorate an ambient environment locally, so that it is not necessary to secure a space surrounding the IC tester, thereby reducing an installing space.

Further, according to the circulating cooling system, the temperature of the cooling air flowing from the heat exchanger 7 to the duct 4C (substantially equal to the temperature of cooling air which flows from the lower portion of the IC tester body 1 to the fan unit 3B2) is always maintained at the target temperature so that the printed boards can be stably cooled.

As mentioned in detail above, the IC tester and the method of cooling the IC tester according to the invention, the IC tester is provided with the circulating means for cooling the heating elements by circulating the cooing air in the IC tester body so that the installing space of the IC tester can be reduced compared with a case where the cooling air is discharged to the side of the IC tester. Further, it is possible to restrain an ambient environment from being deteriorated compared with a case where the cooling air is discharged to the outside of the IC tester body, namely, to the side or upper portion thereof.

What is claimed is:

1. An IC tester having circulating means for circulating cooling air therein, thereby cooling heating elements mounted therein.

2. The IC tester according to claim 1, wherein the circulating means includes cooling means for cooling the cooling air at a constant temperature and supplying it to the heating elements.

3. The IC tester according to claim 1 or 2, wherein the heating elements are shelves through which air is ventilated freely and on which a plurality of printed boards are mounted for effecting various signal processing for testing the ICs.

4. A method of cooling an IC tester comprising circulating cooling air in the IC tester, thereby cooling heating elements mounted therein.

5. The method of cooling an IC tester according to claim 4, further comprising cooling the cooling air at a constant temperature and supplying it to the heating elements.

6. The method of cooling an IC tester according to claim 4, wherein the heating elements comprise shelve through which air is ventilated freely and on which a plurality of printed boards are mounted for effecting various signal processing for testing the ICs.
